(19) United States
(12) Patent Application Publication
(10) Pub. No.: US 2020/0357942 A1
(43) Pub. Date: Nov. 12, 2020

(54) SOLAR CELL MODULE

(71) Applicant: 3M INNOVATIVE PROPERTIES COMPANY, St. Paul, MN (US)

(72) Inventors: Jiaying Ma, Cottage Grove, MN (US); Timothy N. Narum, Lake Elmo, MN (US); Mark B. O'Neill, Stillwater, MN (US); Qihong Nie, Cottage Grove, MN (US); Yuting Wan, Shanghai (CN)

(21) Appl. No.: 16/962,988

(22) PCT Filed: Jan. 30, 2019
(86) PCT No.: PCT/IB2019/050755

§ 371 Date: Jul. 17, 2020

(30) Foreign Application Priority Data
Jan. 30, 2018 (CN) 201810090061.X
Jan. 30, 2018 (CN) 201820157938.8

(51) Int. Cl. H01L 31/048; H01L 31/05; H01L 31/054

(52) U.S. Cl. CPC H01L 31/0481; H01L 31/0547; H01L 31/0508

(57) ABSTRACT

Disclosed is a solar cell module, which comprises: a plurality of solar cells; a light transmitting element disposed on the light receiving side of the plurality of solar cells; a front encapsulant layer between the plurality of solar cells and the light transmitting element; a plurality of tabbing ribbons disposed on the light receiving surfaces of the plurality of solar cells for connecting the plurality of solar cells; and a light redirecting film disposed upon the on-the-cell portion of at least one said tabbing ribbon; the light redirecting film comprises an optical structure layer facing the light transmitting element, for reflecting light toward the interface between the light transmitting element and the air, which light is subsequently totally internally reflected back to the surfaces of the solar cells, wherein the thickness of the light redirecting film is between 20 μm and 115 μm, and the gram weight of the front encapsulant layer is between 400 g/m2 and 500 g/m2.

### TECHNICAL FIELD

The present invention relates to the field of photovoltaic products, and in particular, to a solar cell module.

### BACKGROUND

FIG. 1 shows a typical solar cell module. As shown in FIG. 1, the solar cell module comprises a plurality of solar cells 110 (for ease of display, in the sectional view of FIG. 1, only one solar cell 110 is shown), front encapsulant layer 400, rear encapsulant layer 500, light transmitting element 300, and backsheet or backsheet glass 600; and the plurality of solar cells 110 are connected together by a plurality of tabbing ribbons 120 and the tabbing ribbons 120 are, in general, made of copper. In practice, the light transmitting element 300 is generally composed of a high-strength tempered glass; the front encapsulant layer 400 and rear encapsulant layer 500 are generally composed of ethylene-vinyl acetate copolymer (commonly known as “EVA”) materials; the backsheet 600, on the other hand, is generally composed of polymeric materials containing fluorine as it needs to have good weather resistance. In order to further improve the utilization efficiency of sunlight for the solar cell module, currently, a light redirecting film has been introduced into the solar cell module for reflecting at least some of sunlight that initially does not enter the effective photoelectric conversion region of the solar cell to an interface between the aforementioned light transmitting element 300 and the air; and this portion of sunlight is reflected onto an effective photoelectric conversion region of the solar cell based on the principle of total internal reflection, so as to effectively improve the electricity generation power of the module. For example, U.S. Pat. No. 4,235,643, 5,994,641 and 8,063,299 have disclosed the specific technical solution of applying the aforementioned light redirecting film to the solar cell module.

One of the various technical solutions where the light redirecting film is applied to the solar cell module is that a light redirecting film is disposed over a tabbing ribbon on the surface of a solar cell; for example, the T80-X light redirecting film which is a product of 3M Corporation is disposed over the tabbing ribbon on the surface of the solar cell. As shown in FIG. 2, a specific solution of disposing the light redirecting film over the tabbing ribbon is shown. A plurality of tabbing ribbons are disposed on the light receiving surface of solar cell 110 for connecting the solar cell 110 with the other solar cells 110; and a light redirecting film 200 is disposed upon the on-the-cell 110 portion of at least one of the tabbing ribbon 120. After the light redirecting film 200 is disposed over tabbing ribbon 120 on the surface of the solar cell, at this point, in order for the solar module to pass the test of TC50 treatment when compared with the solutions where no light redirecting film 200 is in place, additional EVA material needs to be added to the front encapsulant layer 400. The TC50 treatment means a treatment with 50 times of thermal cycling with the specific steps as follows: at room temperature, the solar cell module is placed in a climatic chamber; the climatic chamber is closed, so that the solar module can go through the thermal cycle for 50 times in a temperature range of between −40 ° C.±2° C. and 85° C. ±2° C.; and the temperature changing rate between the highest and the lowest temperatures is not more than 100° C./h. At each extreme temperatures, the solar cell module should remain stable for at least 10 min and the duration for one cycle is no more than 6 h. The test results shown in FIGS. 6, 7, and 8 have confirmed this point. In these tests, a standard tabbing ribbon with a thickness x width of 0.20 mm331.5 mm is adopted; and the total thickness of the light redirecting film adopted is 115 μm. Specifically, FIG. 6a is an electroluminescence image of a semi-finished product of a solar cell module that has not gone through the lamination process and not been disposed with the light redirecting film, with the thickness of the front encapsulant layer being 0.66 mm; FIG. 6b is an electroluminescence image of a semi-finished product of a solar cell module that has not gone through the lamination process and has been disposed with the light redirecting film, with the thickness of the front encapsulant layer being 0.66 mm; FIG. 6c is an electroluminescence image of a solar cell module obtained from the semi-finished product of the solar cell module in FIG. 6b after going through the lamination process; FIG. 6d is an electroluminescence image of the solar cell module in FIG. 6c after going through the TC50 test; FIG. 7a is an electroluminescence image of a semi-finished product of a solar cell module that has not gone through the lamination process and has not been disposed with the light redirecting film, with the thickness of the front encapsulant layer being 0.60 mm; FIG. 7b is an electroluminescence image of a semi-finished product of a solar cell module that has not gone through the lamination process and has been disposed with the light redirecting film, with the thickness of the front encapsulant layer being 0.60 mm; FIG. 7c is an electroluminescence image of a solar cell module obtained from the semi-finished product of the solar cell module in FIG. 7b after going through the lamination process; FIG. 7d is an electroluminescence image of the solar cell module in FIG. 7c after going through the TC50 test; FIG. 8a is an electroluminescence image of a semi-finished product of a solar cell module that has not gone through the lamination process and has not been disposed with the light redirecting film, with the thickness of the front encapsulant layer being 0.46 mm; FIG. 8b is an electroluminescence image of a semi-finished product of a solar cell module that has not gone through the lamination process and has been disposed with the light redirecting film, with the thickness of the front encapsulant layer being 0.46 mm; FIG. 8c is an electroluminescence image of a solar cell module obtained from the semi-finished product of the solar cell module in FIG. 8b after going through the lamination process; FIG. 8d is an electroluminescence image of the solar cell module in FIG. 8c after going through the TC50 test.

The electroluminescence image herein is obtained by providing a voltage to the positive and negative electrodes of the solar cell module in an unlit state so that the solar cell module emit light while taking photographs.

Based on these figures, it is clear that after the light redirecting film is disposed over the tabbing ribbon and when the thickness of the front encapsulant layer is relatively thick (e.g., its thickness is 0.66 mm, corresponding to FIG. 6a-FIG. 6d), no obvious cracks are observed on the solar cell after the module has gone through the lamination process and the TC50 treatment. However, when other aspects are kept unchanged and the thickness of the front encapsulate layer is reduced to 0.6 mm (corresponding to FIGS. 7a, 7b, 7c, and 7d), cracks are observed on the solar cell after the module has gone through the lamination process and the TC50 treatment. Furthermore, when the thickness of the front encapsulant layer is reduced to 0.46 mm (corresponding to FIG. 8a-FIG. 8d), more cracks are observed on the solar cell after the module has gone through the lamination process and the TC50 treatment. That is, additional EVA needs to be added to the front encapsulant layer in order to dispose the light redirecting film on the surface of the tabbing ribbon. In the above example, when a light redirecting film with a thickness of 115 μm is disposed over the tabbing ribbon, additional EVA with a thickness of 0.14 mm to 0.2 mm needs to be added to the front encapsulant layer in order for the solar module to pass the test of TC50 treatment.

However, the additional EVA material results in an increase in the overall cost of the module. After the light redirecting film 200 is disposed over the tabbing ribbon 120 on the surface of the solar cell, the thickness of the EVA that needs to be added to the front encapsulant layer 400 is roughly equal to the thickness of the introduced light redirecting film 200. Therefore, it is desirable to reduce the thickness of the introduced light redirecting film, so as to reduce the added thickness of the front encapsulant layer 400, and to effectively reduce the cost of the module. In addition, another advantage of adopting a thinner light redirecting film is that it makes it possible to adopt a thicker tabbing ribbon 120. Adopting a relatively thicker tabbing ribbon 120 can effectively reduce the resistance of the tabbing ribbon, thereby increasing the power output of the module. Nevertheless, after the module has gone through the lamination process, if other aspects of the light redirecting film 200 are kept unchanged, and only its thickness is reduced, then folds are more likely to occur on the thinner light redirecting film 200, which affects not only the power increase of the module, but also the appearance of the module.

### SUMMARY

It is therefore necessary to solve the folding over problem which is easy to happen in a light redirecting film 200 during lamination of solar cell module, when the thin light redirecting film 200 is disposed over a tabbing ribbon on the surface of a solar cell. To solve above-mentioned problem, a solar cell module is provided. The solar cell module comprises: a plurality of solar cells; a light transmitting element disposed on the light receiving side of the plurality of solar cells; a front encapsulant layer between the plurality of solar cells and the light transmitting element; a plurality of tabbing ribbons disposed on the light receiving surfaces of the plurality of solar cells for connecting the plurality of solar cells; and a light redirecting film disposed upon the on-the-cell portion of at least one said tabbing ribbon; the light redirecting film comprises an optical structure layer facing the light transmitting element, for reflecting light toward the interface between the light transmitting element and the air, which light is subsequently totally internally reflected back to the surfaces of the solar cells, wherein the thickness of the light redirecting film is between 20 μm and 115 μm, and the gram weight of the front encapsulant layer is between 400 g/m2 and 500 g /m2.

Preferably, the width of the tabbing ribbons is less than or equal to 1.0 mm, and the result of the light redirecting film's width subtracting the width of the tabbing ribbon on which the light redirecting film is disposed is within a range of 0 to 0.2 mm.

Preferably, the thickness of the light redirecting film is less than 50 μm, and the result of a light redirecting film's width subtracting the width of the tabbing ribbon on which the light redirecting film is disposed is within a range of 0 to 0.1 mm.

Preferably, the width of a light redirecting film is no larger than 120% of the width of the tabbing ribbon on which the light redirecting film is disposed.

Preferably, no light redirecting film is disposed on the tabbing ribbon portions between the solar cells.

Preferably, the material making the front encapsulant layer comprises ethylene-vinylacetate copolymer material.

Preferably, the light redirecting film has a cross web shrinkage value between 0.5% and 3% at a temperature of 150° C.

Preferably, the area of the tabbing ribbons' orthographic projections on a solar cell onto which the tabbing ribbons are disposed is 3% to 6% of the solar cell's surface area.

Preferably, the thickness of the tabbing ribbons is less than the thickness of the solar cells.

Preferably, the optical structure layer comprises a microstructure layer and a light reflecting layer disposed on the microstructure layer and made of metal material.

Preferably, the microstructure layer comprises a plurality of triangular prisms, and the vertex angles of the triangular prisms are within a range between 100° and 140° , preferably within a range between 110° and 130°.

Preferably, lines perpendicular to the triangular prisms' smallest cross sections are defined to be trends of the triangular prisms, and the trends of the triangular prisms are parallel to the lengthwise direction of the light directing film to which the triangular prisms belong.

Preferably, lines perpendicular to the triangular prisms' smallest cross sections are defined to be trends of the triangular prisms, and the trends of the triangular prisms are at an angle with respect to the lengthwise direction of the light directing film to which the triangular prisms belong.

Preferably, the angle is within a range between 1° and 89°.

Preferably, the light redirecting film further comprises an adhesive layer and an insulating substrate layer, the adhesive layer and the optical structure layer being disposed on the two sides in the thickness direction of the insulating substrate layer, and the adhesive layer being disposed on a corresponding tabbing ribbon.

Preferably, the material forming the adhesive layer is obtained by cross linking ethylene-vinylacetate copolymer material.

Preferably, the adhesive layer material as obtained by cross linking ethylene-vinylacetate copolymer material has a gel content of greater than 10%, preferably has a gel content of greater than 20%, more preferably has a gel content of greater than 50%.

Preferably, the material making the adhesive layer is obtained by cross linking an acrylic pressure sensitive adhesive.

In the present invention, disposing a light redirecting film may greatly improve the power generating efficiency of the solar cell module. Also, since the light redirecting film has a thickness of from 20 μm to 115 μm, it allows a gram weight of the front encapsulant layer to be in a range of between 400 g/m2 and 520 g/m2. The gram weight of the front encapsulant layer is directly proportional to the thickness of the front encapsulant layer. The heavier the gram weight is, the greater the surface thickness is, and vice versa. In the present application, because the front encapsulant layer has a light gram weight, the cost of the solar cell module can be reduced.

### BRIEF DESCRIPTION OF THE DRAWINGS

The accompanying drawings are included to facilitate a better understanding of the present invention, and they constitute a part of this Description, and serve to explain the present invention together with the following embodiments. The drawings, however, are not to limit the present invention. In the accompanying drawings:

FIG. 1 is a schematic sectional view of a solar cell module in prior art;

FIG. 2 is a schematic sectional view of a solar cell module provided by the present invention;

FIG. 3a is an electroluminescent image of a semi-finished product of a solar cell module before the lamination process;

FIG. 3b is an electroluminescence image of a solar cell module obtained from the solar cell module in FIG. 3a after the lamination process;

FIG. 3c is an electroluminescence image of a solar cell module having a tabbing ribbon with the thickness×width of 0.14 mm×3.0 mm after the TC50 treatment, wherein the tabbing ribbon is made of copper;

FIG. 3d is an electroluminescence image of a solar cell module having a tabbing ribbon with the thickness×width of 0.17 mm×2.5 mm after the TC50 treatment, wherein the tabbing ribbon is made of copper;

FIG. 3e is an electroluminescence image of a solar cell module having a tabbing ribbon with the thickness×width of 0.20 mm×2.0 mm after the TC50 treatment, wherein the tabbing ribbon is made of copper;

FIG. 3f is an electroluminescence image of a solar cell module having a tabbing ribbon with the thickness×width of 0.25 mm×1.7 mm after the TC50 treatment, wherein the tabbing ribbon is made of copper;

FIG. 4 is a comparison chart showing the light emission efficiencies of the various embodiments of the solar cell modules provided by the present invention;

FIG. 5 is a schematic diagram of the structure of the light redirecting film used in the solar cell module provided by the present invention;

FIG. 6a is an electroluminescence image of a semi-finished product of a solar cell module that has not gone through the lamination process (PRE-LAM) and has not been disposed with the light redirecting film, with the thickness of the front encapsulant layer being 0.66 mm;

FIG. 6b is an electroluminescence image of a semi-finished product of a solar cell module that has not gone through the lamination process and has been disposed with the light redirecting film, with the thickness of the front encapsulant layer being 0.66 mm;

FIG. 6c is an electroluminescence image of a solar cell module obtained from the semi-finished product of the solar cell module in FIG. 6b after the lamination process (POST-LAM);

FIG. 6d is an electroluminescence image of the solar cell module in FIG. 6c after the TC50 treatment;

FIG. 7a is an electroluminescence image of a semi-finished product of a solar cell module that has not gone through the lamination process and not been disposed with the light redirecting film, with the thickness of the front encapsulant layer being 0.60 mm;

FIG. 7b is an electroluminescence image of a semi-finished product of a solar cell module that has not gone through the lamination process and has been disposed with the light redirecting film, with the thickness of the front encapsulant layer being 0.60 mm;

FIG. 7c is an electroluminescence image of a solar cell module obtained from the semi-finished product of the solar cell module in FIG. 7b after the lamination process;

FIG. 7d is an electroluminescence image of the solar cell module in FIG. 6c after the TC50 treatment;

FIG. 8a is an electroluminescence image of a semi-finished product of a solar cell module that has not gone through the lamination process and not been disposed with the light redirecting film, with the thickness of the front encapsulant layer being 0.46 mm;

FIG. 8b is an electroluminescence image of a semi-finished product of a solar cell module that has not gone through the lamination process and has been disposed with the light redirecting film, with the thickness of the front encapsulant layer being 0.46 mm;

FIG. 8c is an electroluminescence image of a solar cell module obtained from the semi-finished product of the solar cell module in FIG. 7b after the lamination process;

FIG. 8d is an electroluminescence image of the solar cell module in FIG. 6c after the TC50 treatment;

FIG. 9 is a comparison chart of the smoothness curves of the light redirecting films with different widths in the solar cell module.

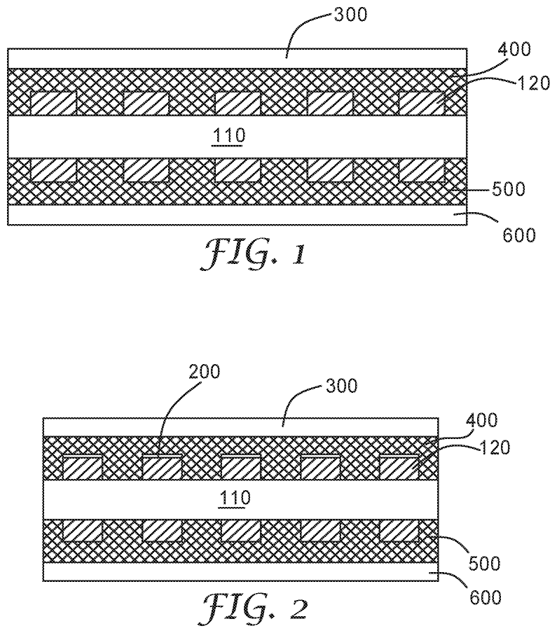

### DETAILED DESCRIPTION

The present invention is described below in details with reference to the accompanying drawings. It should be understood that the embodiments described herein are for illustration and explanation purposes only and are not intended to limit the present invention.

The present invention provides a solar cell module. As shown in FIG. 2, according to one embodiment of the present invention, the solar cell module comprises: a plurality of solar cells 110; a light transmitting element 300 disposed on the light receiving side of the plurality of solar cells 110; a front encapsulant layer 400 between the plurality of solar cells 110 and the light transmitting element 300; a plurality of tabbing ribbons 120 disposed on the light receiving surfaces of the plurality of solar cells 110 for connecting the plurality of solar cells 110; and a light redirecting film 200 disposed upon the on-the-cell portion of at least one of the tabbing ribbon 120. In addition, the solar cell module further comprises a backsheet or backsheet glass 600, as well as a rear encapsulant layer 500 located between the backsheet or backsheet glass 600 and the plurality of solar cells 110. The light redirecting film 200 comprises an optical structure layer facing the light transmitting element 300, for reflecting light towards the interface between the light transmitting element and the air, and such light is subsequently totally internally reflected back to the surfaces of the solar cells. The thickness of the light redirecting film 200 is between 20 μm and 115 μm; and the gram weight of the front encapsulant layer 400 is between 400 g/m² and 500 g/m² (equivalent to that the thickness of the front encapsulant layer is between 0.46 mm and 0.6 mm).

The surface of the light redirecting film 200 facing the light transmitting element 300 is an optical structure layer, which may reflect the incident light that should have irradiated the upper surface of the tabbing ribbon 120 corresponding to the light redirecting film 200; and after the reflected light reaches the light transmitting element 300, it travels within the light transmitting element 300 to the interface between the light transmitting element 300 and the air. Since the light transmitting element 300 is an optically dense medium and air is an optically thinner medium, light can be totally internally reflected at the interface between the light transmitting element 300 and the air, and travel within the front encapsulant layer 400 until it reaches the solar cell 110. Then the light is converted to electrical energy, thereby increasing the power generating efficiency of the solar cell module through the increase in the utilization efficiency of the light.

As previously discussed, a thinner light redirecting film requires only a smaller thickness of the front encapsulant layer 400, and thus the cost of the solar cell module can be reduced. However, a folding over problem may occur during the lamination process of the module when other aspects of the light redirecting film remains the same and its thickness is reduced. The inventors have discovered that the fact as to whether the light redirecting film would be folded over is related not only to the thickness of the light redirecting film itself, but also to the width of the light redirecting film and the relationship between the width of the light redirecting film and the width of the tabbing ribbon where the light redirecting film is located. More specifically, the greater the thickness of the light redirecting film is, the more rigid the light redirecting film is, and the light redirecting film is less prone to fold over during the lamination process of the module; if the light redirecting film is thin but the light redirecting film is wide, it is less prone to fold over during the lamination process of the module; for the relationship between the light redirecting film and the tabbing ribbon, the width of the light redirecting film may be less than or equal to the width of the tabbing ribbon. Certainly, the width of the light redirecting film can also be greater than the width of the tabbing ribbon. In order to increase the utilization efficiency of sunlight, the width of the light redirecting film is preferably no less than the width of the tabbing ribbon.

As a specific scenario, if the width of the tabbing ribbon 120 is less than or equal to 1.0 mm, and if preventing the folding over of the light redirecting film 200 during the lamination process is needed, then the difference obtained by subtracting the width of the tabbing ribbon 120 where it is located from the width of the light redirecting film is preferably within the range of 0 to 0.2 mm. As another specific scenario, if the thickness of the light redirecting film is less than 50 μm, and if preventing the folding over of the light redirecting film during the lamination process is needed, then the difference obtained by subtracting the width of the tabbing ribbon where it is located from width of the light redirecting film is preferably within the range of 0 to 0.1 mm.

In short, the width of the light redirecting film should not exceed 120% of the width of the tabbing ribbon where it is located.

As a specific example, FIG. 9 has shown the simulation calculation result of the smoothness of the light redirecting films obtained through the combination and lamination process of the copper tabbing ribbon with a width of 1.0 mm and the light redirecting films of different widths.

Specifically, modeling and simulation are carried out using the Abacus simulation software. It is assumed that the PET substrate layer of the light redirecting film fits closely with its optical structure layer (there is no relative movement between them); and as the EVA is very soft, sliding is allowed between its PET substrate layer and the EVA bonding layer or between the EVA bonding layer and the copper tabbing ribbon, i.e., relative displacement is allowed. The model is a half domain (the right side is a symmetry face). The symmetry face only allows vertical displacement or deformation. In this case, an even load equal to the lamination pressure of the module, e.g., in a range of from 0.08 MPa to 0.12 MPa, is applied to the entire surface of the light redirecting film. The bottom of the copper tabbing ribbon is fixed. In FIG. 9, the X coordinate represents the thickness of the substrate layer (PET, in this example) of the light redirecting film (the thickness of the PET layer tends to exceed more than half of the total thickness of the light redirecting film), and the Y coordinate represents the smoothness of the light redirecting film. Herein, the smoothness is the difference between the position of the center of the light redirecting film and its edge in a vertical direction. It is easy to understand that the smaller the smoothness value is, the smoother the light redirecting film would be, which further indicates there is no folding over or the degree of the folding over is small, leading to a more acceptable performance.

Specifically, the “full” in FIG. 9 represents that the light redirecting film is 20% wider than the tabbing ribbon where it is located (specifically, the width of the tabbing ribbon is 1 mm, and the width of the light redirecting film on such tabbing ribbon is 1.2 mm); the “half” represents that the light redirecting film is 10% wider than the tabbing ribbon where it is located (specifically, the width of the tabbing ribbon is 1 mm, and the width of the light redirecting film on such tabbing ribbon is 1.1 mm); and the “no” represents that the width of the light redirecting film is the same as the tabbing ribbon where it is located (specifically, the width of the tabbing ribbon is 1 mm, and the width of the light redirecting film on such tabbing ribbon is 1 mm). It is thus clear that when the thickness of the PET layer in the light redirecting film is 75 μm and the width of the light redirecting film is 1.2 mm, the smoothness is less than 5 μm after the lamination process of the module, which is acceptable. However, when the thickness of the PET decreases, the light redirecting film with a width of 1.2 mm may fold over. For example, the inventors actually validated the finding in the laboratory that when the thickness of the PET layer was reduced to 35 μm, the light redirecting film with a width of 1.2 mm would have an unacceptable and obvious folding over problem after the lamination process of the module.

Additionally, FIG. 9 shows that when the width of the light redirecting film is 1.1 mm, even though the thickness of the PET layer is reduced to 20 μm, its smoothness is normally not greater than 5 μm after the lamination process of the module, which is acceptable. Furthermore, the inventors actually validated the finding in the laboratory that when the thickness of the PET layer was reduced to 35 μm, the degree of folding over of the light redirecting film with a width of 1.1 mm after the lamination process of the module is acceptable. Another conclusion that can be drawn from FIG. 9 is that when the width of light redirecting film is the same as that of the tabbing ribbon where it is located, which are both 1.0 mm, then within the range of the thickness of the PET layer as shown in FIG. 9, the smoothness of the light redirecting film after the lamination process of the module is 0, i.e., no folding over occurs.

In order to minimize the folding over of the light redirecting film, it is necessary for the light redirecting film to have a minimum displacement during the lamination process of the module. This requires that the adhesive used to fix the light redirection film should not move at the high temperature during the lamination process of the module. As a result, the key is that the adhesive is pre-crosslinked prior to the lamination process of the module.

### EMBODIMENTS

The adhesive is crosslinked using electron beam irradiation. For the light redirecting film, ethylene-vinyl acetate copolymer (EVA) may be adopted (e.g., the extrudable ethylene-vinyl acetate copolymer resin Elvax 3175 or Elvax 3180 made by DuPont located in Wilmington, Del., USA may be selected) as the adhesive. The adhesive was exposed to an electron beam processor of 120 kV and 7.5 Mrads and a line speed of 200 feet per minute. The lamination test shows that when a treated light redirecting film was adopted, almost no displacement was observed. According to the ASTM D2765-01 “Standard Test Method for the Gel Content and Expansion Rate of Crosslinked Ethylene Plastics,” the gel content is used to measure the effect of crosslinking. Six duplicated samples containing crosslinking adhesives and six duplicated samples without crosslinking adhesives were tested. Table 1 lists the gel content results.

TABLE 1
Gel Content Results for Crosslinked and
Uncrosslinked Light Redirecting Films

| Gel Content % | Adhesive Type |
|---|---|
| 58.54% | Crosslinked |
| 63.52% | Crosslinked |
| 61.57% | Crosslinked |
| 53.72% | Crosslinked |
| 58.66% | Crosslinked |
| 52.71% | Crosslinked |
| 2.66% | Uncrosslinked |
| 1.52% | Uncrosslinked |
| 2.18% | Uncrosslinked |
| 5.34% | Uncrosslinked |
| 2.91% | Uncrosslinked |
| 3.87% | Uncrosslinked |

The above results show that the electron beam irradiation has increased the gel content significantly. It is expected that the gel content can be adjusted by changing the conditions of the process, in particular the dosage levels and line speed. The displacement of the light redirecting film is also influenced by other factors such as the width of the tabbing ribbon, lamination temperature, vacuum process, and lamination time period. As a result, an acceptable light redirecting film displacement can be achieved within a range of crosslinking degrees. A gel content of more than 10% is needed; and more preferably, the gel content of the adhesive after crosslinking is greater than 20%, or greater than 50%.

When a thin light redirecting film is disposed on the tabbing ribbon, its PET layer will be the main insulating layer between the tabbing ribbons on the adjacent cells. In order to ensure a certain degree of electrical insulation, it is desirable that the PET layer has a certain thickness. However, as previously mentioned, when the PET is thick, the light redirecting film will also be thick, which results in an increase in the thickness of the front encapsulant layer, which in turn increases the cost of the solar cell module. Thus, when a thin light directing film is used, additional insulation means is needed to ensure a certain degree of electrical insulation. However, this increases the complexity of the light redirecting film and needs a careful positioning of the light redirecting film so that the insulating portion is between the cells. To address this problem, the inventors have discovered through experiments that, as a different and simpler solution, the light redirecting film may be disposed on the tabbing ribbon provided that the light redirecting film between the solar cells are removed. That is, no light redirecting film is disposed on a portion of the tabbing ribbon located between the solar cells.

It is important to note that when the light redirecting film is disposed on the tabbing ribbon, an entire sheet of light redirecting film material needs to cover all the tabbing ribbons; and then the light redirecting film material is cut to obtain light redirecting films disposed on the tabbing ribbon of each solar cell respectively. The temperature for the lamination process is at around 150° C. During the lamination process of the module, the light redirecting film will shrink. At a temperature of 150° C., a larger transverse (cross web) shrinkage of the light redirecting film better ensures that the adjacent two light redirecting films are completely disconnected. In addition, a larger transverse (cross web) shrinkage of the light redirecting film leads to a lower cost of the light redirecting film.

The cost of solar cell module may be further reduced by adopting a light redirecting film with a shrinkage of greater than 0.5%. Thus, it is beneficial to select a transverse shrinkage of the light redirecting film in a range of from 0.5% to 3% at a temperature of 150° C. In addition to reducing the cost of solar cell module and preventing light redirecting films from folding over during the lamination process of the module, another advantage of adopting a thinner and wider light redirecting film is that it allows for wider and thinner tabbing ribbons to be used on thinner solar cells.

It is well known that the width of the tabbing ribbon is typically limited in standard solar cell modules that do not have a light redirecting film; otherwise, the tabbing ribbon will shield more parts of the solar cell, which reduces the effective photoelectric conversion area of the solar cell accordingly. In general, the area of the tabbing ribbon occupies about 3% of the surface area of the solar cell where it is located. In order to reduce the resistive losses caused by the tabbing ribbon, the tabbing ribbon must be thicker so as to increase the use amount of copper. In today's standard solar cell modules, the thickness of the solar cell is about 180 μm; however, the thickness of the tabbing ribbon is about from 220 μm to 250 μm. Thus, the thickness of the solar cell is limited by the thickness of the tabbing ribbon. On the other hand, in solar cell modules, the solar cell 110 typically contains silicon-containing materials, whereas the tabbing ribbon is typically made of a metallic material. It is easy to understood that the coefficient of thermal expansion of the silicon is less than the coefficient of thermal expansion of the metal material. The tabbing ribbon in a solar cell module is typically made of copper with low resistivity. The coefficient of thermal expansion of copper is 7 times as much as silicon. As the coefficient of thermal expansion of the tabbing ribbon is much higher than the coefficient of thermal expansion of the solar cell, the cells are liable to break after the solar cell module is used for a long time.

After repeated tests and research, the inventors discovered that the larger the width of the tabbing ribbon is and the smaller the thickness of the tabbing ribbon is, the less likely the solar cells will break. This is demonstrated by the following test results.

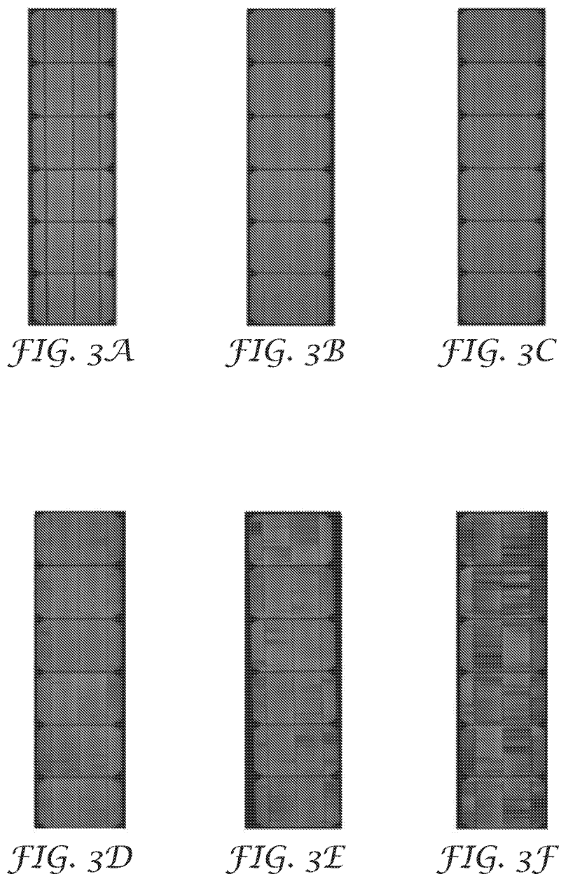

Specifically, FIGS. 3a to 3f show electroluminescence images obtained after the TC50 treatment with respect to the solar cell module having a tabbing ribbon with the thickness×width of 0.14 mm×3.0 mm, solar cell module having a tabbing ribbon with the thickness×width of 0.17 mm×2.5 mm, solar cell module having a tabbing ribbon with the thickness×width of 0.20 mm×2.0 mm, and solar cell module having a tabbing ribbon with the thickness×width of 0.25 mm×1.7 mm. In these embodiments, the solar cells adopted are all mono-crystalline silicon solar cells provided with 3 bus bars and with a thickness of 200 μm; and the tabbing ribbons adopted are provided with a tin coating of about 20 μm; and light redirecting films with a total thickness of 115 μm are disposed on the tabbing ribbon of each of these (the width of these light redirecting films is 0.5 mm greater than the width of the tabbing ribbons where they are located); and the width of the front encapsulant layer and the width of the rear encapsulant layer of each solar cell are both 0.46 mm. As shown in FIGS. 3c, 3d, 3e, and 3f, after the TC50 treatment, the appearance of the solar cell module having a tabbing ribbon with the thickness×width of 0.14 mm×3.0 mm was substantially kept normal; however, starting from the solar cell module having a tabbing ribbon with the thickness×width of 0.17 mm×2.5 mm, there has been cell breaks. Furthermore, the cell breaks in solar cell module having a tabbing ribbon with the thickness×width of 0.20 mm×2.0 mm is more serious than the solar cell module having a tabbing ribbon with the thickness×width of 0.17 mm×2.5 mm; the cell breaks in solar cell module having a tabbing ribbon with the thickness×width of 0.25 mm×1.7 mm is even more obvious than the solar cell module having a tabbing ribbon with the thickness×width of 0.20 mm×2.0 mm. Thus, these tests show that tabbing ribbons that are wider and thinner have significantly reduced the heat and mechanical stress on the solar cells.

On the other hand, by placing thinner and wider light redirecting films on the tabbing ribbons, it becomes possible to adopt wider and thinner tabbing ribbons. This is because disposing a light redirecting film on the tabbing ribbon is equivalent to transforming a portion that is masked earlier by the tabbing ribbon into a portion that is capable of reflecting light and reusing light, thereby increasing the utilization efficiency of light by the solar cell. Thus, after the light redirecting film is disposed on the tabbing ribbon, the area occupied by the ribbon on the solar cell where it is located can be increased; that is, a wider tabbing ribbon may be adopted. Preferably, at this point, the area of the front projection of the tabbing ribbon on the solar cell where it is located may be 3% to 6% of the area of the surface of the solar cell where it is located.

Next, with reference to FIG. 4, the power generating efficiency of the solar cell module is illustrated before and after applying a light redirecting film with a total thickness of 115 μm to the solar cell module having a tabbing ribbon with the thickness×width of 0.14 mm×3.0 mm, solar cell module having a tabbing ribbon with the thickness×width of 0.17 mm×2.5 mm, solar cell module having a tabbing ribbon with the thickness×width of 0.20 mm×2.0 mm, solar cell module having a tabbing ribbon with the thickness×width of 0.25 mm×1.7 mm, and solar cell module having a tabbing ribbon with the thickness×width of 0.15 mm×1.5 mm as in the embodiments of FIGS. 3a-3f. A collimated solar simulator is utilized to obtain these results.

As shown in FIG. 4, the power generating efficiency of a solar cell module (the “TC-50” portion in the figure) having a tabbing ribbon with the thickness×width of 0.14 mm×3.0 mm, which has gone through the lamination process (i.e., the above light redirecting film has been disposed on the tabbing ribbon), and the TC50 test, is 18.26%; the power generating efficiency of a solar cell module (the “PRE-LAM” portion in the figure) having a tabbing ribbon with the thickness×width of 0.14 mm×3.0 mm, which has not gone through the lamination process (i.e., the above light redirecting film has not been disposed on the tabbing ribbon), is 17.91%; the power generating efficiency of a solar cell module (the “POST-LAM” portion in the figure) having a tabbing ribbon with the thickness×width of 0.14 mm×3.0 mm, which has gone through the lamination process (i.e., the above light redirecting film has been disposed on the tabbing ribbon) but not the TC50 test, is 18.29%.

As shown in FIG. 4, the power generating efficiency of a solar cell module having a tabbing ribbon with the thickness×width of 0.17 mm×2.5 mm, which has gone through the lamination process (i.e., the above light redirecting film has been disposed on the tabbing ribbon, the “POST-LAM” portion in the figure), is 18.425%; the power generating efficiency of a solar cell module (the “PRE-LAM” portion in the figure) having a tabbing ribbon with the thickness×width of 0.17 mm×2.5 mm, which has not gone through the lamination process (i.e., the above light redirecting film has not been disposed on the tabbing ribbon), is 18.205%; and the power generating efficiency of a solar cell module (the “TC-50” portion in the figure) having a tabbing ribbon with the thickness×width of 0.17 mm×2.5 mm, which has gone through the lamination process (i.e., the above light redirecting film has been disposed on the tabbing ribbon) and the TC50 test, is 18.195%.

As shown in FIG. 4, the power generating efficiency of a solar cell module having a tabbing ribbon with the thickness×width of 0.2 mm×2.0 mm, which has gone through the lamination process (i.e., the above light redirecting film has been disposed on the tabbing ribbon, the “POST-LAM” portion in the figure), is 18.365%; the power generating efficiency of a solar cell module (the “PRE-LAM” portion in the figure) having a tabbing ribbon with the thickness×width of 0.2 mm×2.0 mm, which has not gone through the lamination process (i.e., the above light redirecting film has not been disposed on the tabbing ribbon), is 18.265%; and the power generating efficiency of a solar cell module (the “TC-50” portion in the figure) having a tabbing ribbon with the thickness×width of 0.2 mm×2.0 mm, which has gone through the lamination process (i.e., the above light redirecting film has been disposed on the tabbing ribbon) and the TC50 test, is 17.77%.

As shown in FIG. 4, the power generating efficiency of a solar cell module having a tabbing ribbon with the thickness×width of 0.25 mm×1.7 mm, which has gone through the lamination process (i.e., the above light redirecting film has been disposed on the tabbing ribbon, the “POST-LAM” portion in the figure), is 18.395%; the power generating efficiency of a solar cell module having a tabbing ribbon with the thickness×width of 0.25 mm×1.7 mm, which has not gone through the lamination process (i.e., the above light redirecting film has not been disposed on the tabbing ribbon, the “PRE-LAM” portion in the figure), is 18.385%; and the power generating efficiency of a solar cell module (the “TC-50” portion in the figure) having a tabbing ribbon with the thickness×width of 0.25 mm×1.7 mm, which has gone through the lamination process (i.e., the above light redirecting film has been disposed on the tabbing ribbon) and the TC50 test, is 16.415%.

As shown in FIG. 4, the power generating efficiency of a solar cell module having a tabbing ribbon with the thickness×width of 0.15 mm×0.15 mm, which has gone through the lamination process (i.e., the above light redirecting film has been disposed on the tabbing ribbon, the “POST-LAM” portion in the figure), is 18.19%; the power generating efficiency of a solar cell module (the “PRE-LAM” portion in the figure) having a tabbing ribbon with the thickness×width of 0.15 mm×0.15 mm, which has not gone through the lamination process (i.e., the above light redirecting film has not been disposed on the tabbing ribbon), is 18.18%; and the power generating efficiency of a solar cell module (the “TC-50” portion in the figure) having a tabbing ribbon with the thickness×width of 0.15 mm×0.15 mm, which has gone through the lamination process (i.e., the above light redirecting film has been disposed on the tabbing ribbon) and the TC50 test, is 17.96%.

The above results show that before the lamination process of the module (i.e., before the light redirecting film is disposed on the tabbing ribbon), the power generating efficiency is low for the solar cell module that has adopted a wide tabbing ribbon because many areas on the solar cell thereof are covered by the tabbing ribbon. However, after the lamination process of the module (i.e., after the light redirecting film is disposed on the tabbing ribbon), the power generating efficiency of the solar cell modules that adopt a wider tabbing ribbon is close to the power generating efficiency of the other solar cell modules. Obviously, this change demonstrates that the light redirecting film disposed on the tabbing ribbon has effectively reduced the adverse effect that a wider tabbing ribbon would cover a larger surface area of the solar cell. Furthermore, after the TC50 treatment, only a slight decrease of the power generating efficiency was observed for the solar cell modules that have been disposed with tabbing ribbons with the thickness x width of 0.14 mm×3.0 mm and light redirecting films disposed on such tabbing ribbons, which in turn demonstrates that the design is relatively stable.

Next, a test is conducted to prove that when a thinner light redirecting film is used in conjunction with the respective tabbing ribbons with different thicknesses, the power generating efficiency of the solar cell modules will not be affected.

As shown in Table 2 in what follows, light redirecting films and the tabbing ribbons of different thicknesses are applied in the standard solar cell modules (the thickness of the solar cell is between 180 μm and 200 μm with three main grid lines; the width for each light redirecting film is 2.0 mm; the width for each tabbing ribbon is 1.5 mm); and no additional EVA is added to the front encapsulant layer of the solar cell; and the total thickness of the light redirecting film and the tabbing ribbon is held constant, which is 0.255 mm. It can be verified through the test that the different combinations of the light redirecting films and the tabbing ribbons all can pass the test of the TC50 treatment. Also, Table 1 has shown that after the TC50 treatment, the power generating efficiency of the solar cell modules adopting these combinations of tabbing ribbons and light directing films do not decrease. Thus, the results in Table 2 shows that the introduction of light redirecting film makes it possible for the adoption of a tabbing ribbon with a thickness that is less than or close to the thickness of the solar cell, without causing the power generating efficiency of the modules to decrease. On the other hand, because the overlapping portions between the two are large, the adoption of thinner and wider tabbing ribbons makes it easier to align with the thinner and wider light redirecting films thereon.

TABLE 2

| | | Total thickness | |
|---|---|---|---|
| Thickness of | Thickness | of light redirecting | |
| light redirecting | of tabbing | film and tabbing | Reduction in power |
| film | ribbon | ribbon | generating efficiency after |
| (mm) | (mm) | (mm) | TC50 experiment |
| 0.115 | 0.14 | 0.255 | None (through |
| | | | electroluminescent |
| | | | measurement; for example, in |
| | | | the photograph, if no |
| | | | breakage or color blackening |
| | | | is observed on the cell |
| | | | surface, it is determined that |
| | | | the power generating |
| | | | efficiency of the cell module |
| | | | has not decreased) |
| | | | For the electroluminescent |
| | | | measurement, an EL scanner |
| | | | MPS-1000 made by ASIC |
| | | | China was used; and the |
| | | | samples are connected with |
| | | | the positive and negative |
| | | | electrodes of the device that |
| | | | was loaded with a 9.0 A |
| | | | constant current; and the EL |
| | | | scanning images are observed |
| | | | and recorded. |
| 0.0825 | 0.1725 | 0.255 | None (through |
| | | | electroluminescent |
| | | | measurement) |
| 0.0675 | 0.1875 | 0.255 | None (through |
| | | | electroluminescent |
| | | | measurement) |
| 0.0525 | 0.2025 | 0.255 | None (through |
| | | | electroluminescent |
| | | | measurement) |

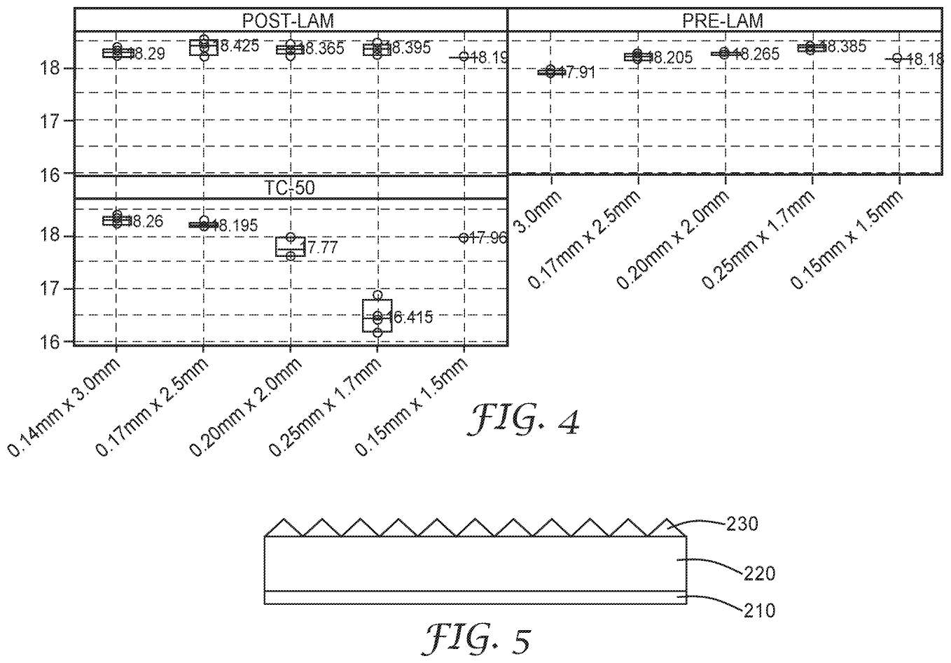

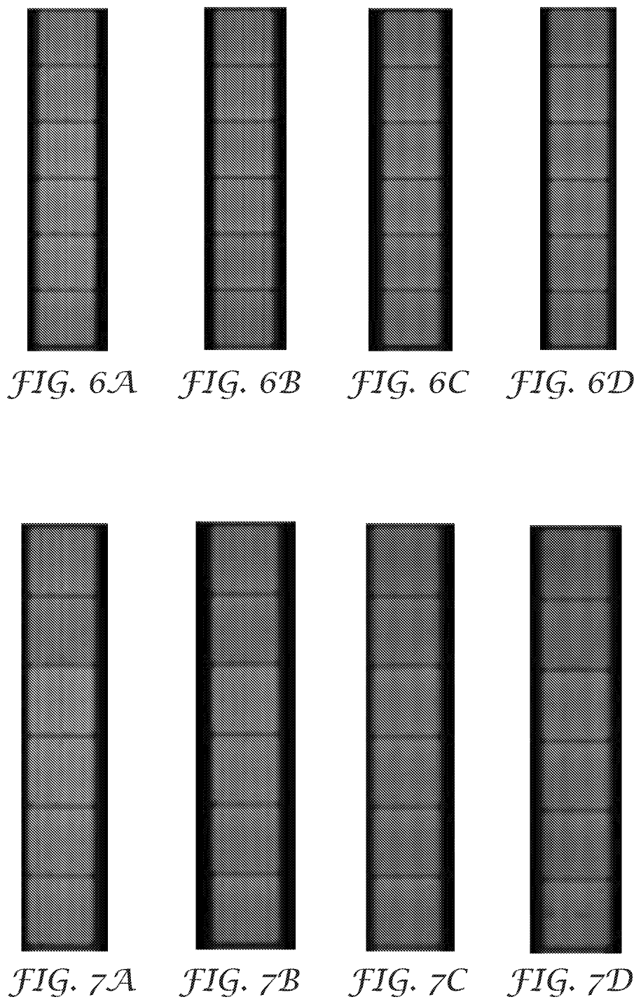

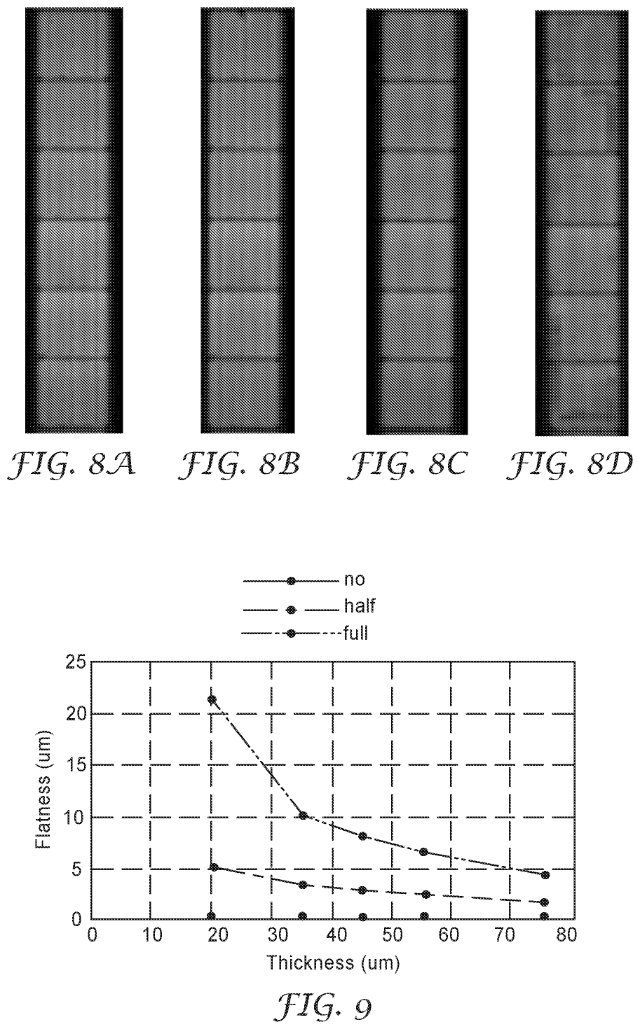

In this embodiment, there is no particular specification with respect to the structure adopted by the light redirecting film, as long as it can realize the following function: “reflecting light towards the interface between the light transmitting element and the front encapsulant layer; and after the reflected light travels to the interface between the light transmitting element 110 and the air, the light is subsequently totally internally reflected back to the surfaces of the solar cells by the interface between the light transmitting element and the air.” For example, as shown in FIG. 5, a light redirecting film 200 is provided, comprising an insulating substrate layer 220, an optical structure layer 230 disposed on one surface of the insulating substrate layer 220, and a bonding layer 210 disposed on the surface of the insulating substrate layer 220 that is opposite to the surface where the optical structure layer 230 is located. The optical structure layer 230 may comprise a micro-structure layer (not shown), and a reflective layer disposed on the micro-structure layer, which is made of metallic materials (not shown).

The insulating substrate layer 220 may be made by utilizing one or a plurality of polymeric films. For example, the insulating substrate layer may be made of one or a plurality of the following polymers: cellulose acetate butyrate, cellulose-acetate propionate, cellulose triacetate, poly(methyl)acrylate, polyethylene glycol terephthalate, polynaphthalene diol ester; copolymers or mixtures based on naphthalene dicarboxylic acid; copolymer of polyethersulfone, polyurethane, polycarbonate, polyvinyl chloride, syndiotactic polystyrene, cycloolefin as well as materials based on organosilicone.

In the optical structure layer, the micro-structure layer also includes a polymeric material. Its ingredients may be the same as the substrate layer 220, or may be different. In some embodiments, the material is poly(meth)acrylate. In the embodiment as shown in FIG. 5, the micro-structure layer includes a plurality of triangular prisms. In order to ensure that the light reflected by the optical structure layer 230 is totally reflected at the interface between the light transmitting element and the air, preferably, for the above two light redirecting films, the vertex angles of the triangular prisms are within a range of between 100° and 140° , and preferably within a range of between 110° and 130° . In this embodiment, 120° is used. In addition, the straight lines perpendicular to the triangular prisms' smallest cross sections are defined to be trends of the triangular prisms; and then the light redirecting film adopted in the present invention may be divided into two types. In the first light redirecting film, the trends of the triangular prisms are parallel to the length direction of the light directing film. In the second light redirecting film, the trends of the triangular prisms are at an angle with respect to the length direction of the light directing film. For example, the angle is in a range of from 1° to 89°. The reflective layer is disposed on the triangular prism. The reflective layer can be formed by utilizing a sputtering process. The materials for the reflective layer can be metallic materials such as silver, aluminum, platinum, titanium, silver alloys, aluminum alloys, platinum alloys, titanium alloys, and the like. The thickness of the reflective layer can be approximately from 30 nm to 100 nm, and preferably from 35 nm to 60 nm.

In the present invention, the specific materials for the bonding layer 210 are not limited. As one of the embodiments of the present invention, as noted above, the materials for making the bonding layer 210 may be obtained through crosslinking ethylene-vinyl acetate copolymer (i.e., EVA materials, such as the extrudable ethylene-vinyl acetate copolymer resin Elvax 3175 or Elvax 3180 made by DuPont located in Wilmington, Del., USA) after the electron beam radiation treatment. The crosslinked ethylene-vinyl acetate copolymer material not only has good bonding properties but also has a greater shear strength. After bonding the light redirecting film 200 to the tabbing ribbon with bonding layer 210 made of crosslinked ethylene-vinyl acetate copolymer during the lamination process, the light redirecting film 200 is not likely to be displaced. As yet another embodiment of the present invention, the materials for the bonding layer 210 may be made from crosslinking pressure sensitive acrylic adhesive (e.g., FL501 pressure sensitive acrylic adhesive tape made by 3M Corporation located in St. Paul, Minn., USA) after heat treatment.

In order to ensure the bonding strength, the thickness of the bonding layer 210 may be 25 μm. In the present invention, the overall thickness of the light redirecting film can be adjusted by adjusting the thickness of the insulating substrate layer and the thickness of the optical structure layer. For example, in order to obtain a light redirecting film with a thickness of 115 μm, the thickness of the bonding layer may be 25 μm, the thickness of insulating substrate layer may be 75 μm, and the thickness of the optical structure layer may be 15 μm. In order to obtain a light redirecting film with a thickness of 82.5 μm, the thickness of the bonding layer may be 25 μm, the thickness of insulating substrate layer may be 50 μm, and the thickness of the optical structure layer may be 7.5 μm. In order to obtain a light redirecting film with a thickness of 67.5 μm, the thickness of the bonding layer may be 25 μm, the thickness of insulating substrate layer may be 35 μm, and the thickness of the optical structure layer may be 7.5 μm. In order to obtain a light redirecting film with a thickness of 52.5 μm, the thickness of the bonding layer may be 25 μm, the thickness of insulating substrate layer may be 20 μm, and the thickness of the optical structure layer may be 7.5 μm.

It can be understood that, the above embodiments are only exemplary embodiments employed for illustration of principles of the present invention, and do not limit the present invention. For those of ordinary skill in the art, various variations and modifications may be made without departing from the spirit and essence of the present invention, which variations and modifications are also considered as falling within the protection scope of the present invention.

1. A solar cell module, comprising:
a plurality of solar cells;
a light transmitting element disposed on the light receiving side of the plurality of solar cells;
a front encapsulant layer between the plurality of solar cells and the light transmitting element;
a plurality of tabbing ribbons disposed on the light receiving surfaces of the plurality of solar cells for connecting the plurality of solar cells; and
a light redirecting film disposed upon the on-the-cell portion of at least one said tabbing ribbon;
the light redirecting film comprises an optical structure layer facing the light transmitting element, for reflecting light toward the interface between the light transmitting element and the air, which light is subsequently totally internally reflected back to the surfaces of the solar cells, wherein the thickness of the light redirecting film is between 20 μm and 115 μm, and the gram weight of the front encapsulant layer is between 400 g/m² and 500 g /m².

2. The solar cell module of claim 1, wherein the width of the tabbing ribbons is less than or equal to 1.0 mm, and the result of the light redirecting film's width subtracting the width of the tabbing ribbon on which the light redirecting film is disposed is within a range of 0 to 0.2 mm.

3. The solar cell module of claim 1, wherein the thickness of the light redirecting film is less than 50 μm, and the result of a light redirecting film's width subtracting the width of the tabbing ribbon on which the light redirecting film is disposed is within a range of 0 to 0.1 mm.

4. The solar cell module of claim 1, wherein the width of a light redirecting film is no larger than 120% of the width of the tabbing ribbon on which the light redirecting film is disposed.

5. The solar cell module of claim 1, wherein no light redirecting film is disposed on the tabbing ribbon portions between the solar cells.

6. The solar cell module of claim 1, wherein the material making the front encapsulant layer includes ethylene-vinylacetate copolymer material.

7. The solar cell module of claim 1, wherein the light redirecting film has a cross web shrinkage value between 0.5% and 3% at a temperature of 150° C.

8. The solar cell module of claim 1, wherein the area of the tabbing ribbons' orthographic projections on a solar cell onto which the tabbing ribbons are disposed is 3% to 6% of the solar cell's surface area.

9. The solar cell module of claim 1, wherein the thickness of the tabbing ribbons is less than the thickness of the solar cells.

10. The solar cell module of claim 1, wherein the optical structure layer comprises a microstructure layer and a light reflecting layer disposed on the microstructure layer and made of metal material.

11. The solar cell module of claim 10, wherein the microstructure layer comprises a plurality of triangular prisms, and the vertex angles of the triangular prisms are within a range between 100° and 140°, preferably within a range between 110° and 130°.

12. The solar cell module of claim 11, wherein lines perpendicular to the triangular prisms' smallest cross sections are defined to be trends of the triangular prisms, and the trends of the triangular prisms are parallel to the lengthwise direction of the light directing film to which the triangular prisms belong.

13. The solar cell module of claim 11, wherein lines perpendicular to the triangular prisms' smallest cross sections are defined to be trends of the triangular prisms, and the trends of the triangular prisms are at an angle with respect to the lengthwise direction of the light directing film to which the triangular prisms belong.

14. The solar cell module of claim 13, wherein the angle is within a range between 1° and 89°.

15. The solar cell module of claim 1, wherein the light redirecting film further comprises an adhesive layer and an insulating substrate layer, the adhesive layer and the optical structure layer being disposed on the two sides in the thickness direction of the insulating substrate layer, and the adhesive layer being disposed on a corresponding tabbing ribbon.

16. The solar cell module of claim 15, wherein the material forming the adhesive layer is obtained by cross linking ethylene-vinylacetate copolymer material.

17. The solar cell module of claim 16, wherein the adhesive layer material as obtained by cross linking ethylene-vinylacetate copolymer material has a gel content of greater than 10%, preferably has a gel content of greater than 20%, more preferably has a gel content of greater than 50%.

18. The solar cell module of claim 15, wherein the material making the adhesive layer is obtained by cross linking an acrylic pressure sensitive adhesive.
